(19) United States
(12) Patent Application Publication
(10) Pub. No.: US 2011/0074403 A1
(43) Pub. Date: Mar. 31, 2011

(54) HIGH-SENSITIVITY, IN-VIVO, AND DYNAMIC DETECTION OF MAGNETIC PARTICLES WITHIN LIVING ORGANISM USING A PROBE-TYPE SQUID SYSTEM

(75) Inventors: Herng-Er Horng, Taipei Country (TW); Rex Chin-Yih Hong, Taipei City (TW); Hong-Chang Yang, Taipei City (TW); Shieh-Yueh Yang, Taipei County (TW); Jen-Jie Chieh, Taipei City (TW)

(73) Assignees: Herng-Er Horng, Taipei County (TW); Rex Chin-Yih Hong, Taipei City (TW); Hong-Chang Yang, Taipei City (TW); Shieh-Yueh Yang, Taipei County (TW)

(21) Appl. No.: 12/571,220

(22) Filed: Sep. 30, 2009

(51) Int. Cl. G01R 33/02

(52) U.S. Cl. 324/248

(57) ABSTRACT

The present invention provides a probe-type SQUID system to detect magnetic particles stored in the living organisms or magnetic-labeling indicators for immunoassays and tumor or other applications. The probe-type SQUID system comprises a probe union, a SQUID union and a connecting electrically conducting wires such as copper wires, wherein the probe union is coupled with a cooling module such as TE cooler module to avoid power heating so that the probe can approach to the living organism to detect magnetic particles with high-sensitivity.

### FIELD OF THE INVENTION

The present invention relates to a probe-type SQUID system. More particularly, the present invention relates to using the probe-type SQUID system to detect magnetic particles stored in living organism or magnetic-labeling indicators for immunoassays and tumor or other application.

### BACKGROUND OF THE INVENTION

Magnetic nanoparticles within bodies are the metal and metallic oxide particles with bio-function coating, which are manufactured from either a physiology reaction in living beings or an artificial synthesis. The natural organic ones within bodies include copper group, like ceruplasmin and hCtr human copper transport protein, iron type, such as transferrin and hemosiderin, etc. Because they are the indicators related to Wilson disease, diseases of iron deficiency anemia, and hemochromatosis, their amount are usually examined by blood tests, invasive biopsy examines, and some noninvasive methods, such as magnetic resonance image (MRI) and SQUID-Biosusceptometry. Between them, blood tests are the cheapest but low sensed and specific; invasive biopsy examines are dangerous especially for the old, pregnant, etc. even though it owns the advantages of high sensitivity and specificity. Similarly, although MRI and SQUID-biosusceptometry with the high sensitivity and specificity are noninvasive, the drawbacks of high-cost/maintenance and complicate operating are difficult for wide publication. Further, the SQUID-biosusceptometry using SQUID to detect the signal directly, which has the drawbacks that has big interference and noise, and the detecting signal would be low.

For artificial synthesis, those are usually specific for the biomagnetism applications, classified into two kinds, i.e. the type of dynamics controlling, like cell separation, tumor treatment, drug deliver, and the type of detection, such as tumor diagnosis, immunoassay, etc. The last kind, in other words, is that these particles as a magnetic labeling are bound to the target proteins or molecules, and then results in the variation of the specific magnetic susceptibility for the determination of the position or the amount of target ones.

In the detection of magnetic nanoparticles, the requirement of high sensitivity is important because it relates to the successful possibility of curing disease in the early stage disease. For example, in tumor diagnosis, the tumor size of 1 mm generally indicates that the tumor cells are as more as one millions. In this stage of the tumor growth, the tumor transferring to other locations in the torso are usually happened. So the tumor even is found and then removed away by the surge, but sometimes another tumor in other positions of the torso grows up in few days later. The commercial ultrasonography and MRI (magnetic resonance image) technology are limited to the spatial resolutions around several millimeters. However, by SQUID detector detecting the tumor labeled with magnetic nanoparticles, the sensitivity could be improved to micrometer scale. There have been some inventions about the SQUID which connects with a probe to detect magnetic materials. For example, U.S. Pat. No. 5,293,119 discloses an electromagnetic microscope for evaluation of electrically conductive and magnetic materials, which combines SQUID with a probe for use in nondestructive evaluation to evaluate many metal high-technology products or in public infrastructure. However, there has no invention or concept about the probe type SQUID for detecting magnetic particles within living beings.

### SUMMARY OF THE INVENTION

The present invention relates to a probe-type superconducting quantum interference device (SQUID) system for detecting magnetic particles within a living oragnism, comprising: (a) a probe union, which has a double D-shape pickup coil inserted in the center of a excitation coil, for closing to the living organism, wherein the probe union is coupled with a cooling module such as TE cooler module to avoid power heating, (b) a SQUID union comprising a SQUID surrounded by a input coil is inserted in a Dewar and within a shielding can, and (c) a connecting electrically conducting wire sych as copper wire for transferring the signal from the pickup coil of the probe to the input coil.

The present invention further relates to a non-invasive method for detecting magnetic particles within a living organism by a probe-type SQUID comprising (a) a probe union, which has a double D-shape pickup coil inserted in the center of a excitation coil, for approaching to a sample, wherein the probe union is coupled with a cooling module such as TE cooler module to avoid power heating, (b) a SQUID union comprising a SQUID surrounded by a input coil is inserted in a Dewar and within a shielding can, and (c) a connecting electrically conducting wire such as copper wire for transferring the signal from the pickup coil of the probe to the input coil, the method comprises (1) approaching the living organism with the probe to magnetize and sense signal from the living organism, (2) the connecting electrically conducting wires transfer the signal from the pickup coils of the probe to the input coil surrounding SQUID sensor, and (3) generating magnetic signal intensity to evaluate the magnetic particles in the living organism.

### BRIEF DESCRIPTION OF THE DRAWINGS

FIG. 1 shows scheme of a probe type of SQUID system.

FIG. 2 shows (a) the noise spectrum, and (b) the long-term stability testing of this system.

FIG. 3 shows (a) the sample photo shows that the capillary of 0.9 mm in inner diameter was filled with magnetic fluids of 0.1 emu/g, and a reference alumina foil was place in the polystyrene cavity under the pig skin and on the polystyrene surface. (b) The typical scanning pattern of B_{0°} and B_{90°} at the distance between the probe and the pigskin of 1 cm. (c) The magnetic image is constructed from the scanning pattern.

FIG. 4 shows bio junction measurement of a hole filled with anti-CRP coating magnetic fluids of 0.1 emu/g and 0.8 c.c. and CRP solution of 0.1 mg/L and 0.1 c.c.

FIG. 5 shows the sensitivity test was executed by different distance between the probe and different holes filled with magnetic fluids.

FIG. 6 shows the photo of the anesthetized rat, which lay on the board with the coordinates and was marked with its xiphoid.

FIG. 7 shows (a) the scanning pattern across the rat torso over a liver; (b) The long-term measurement of liver susceptibility; (c) fast scanning liver and heart organs in turns.

### DETAILED DESCRIPTION OF THE INVENTION

In the present invention, the framework of the probe-type SQUID system is utilized to magnetize and sense the sample efficiently by the probe composed of the pickup coil and excitation coil for closing to the sample. Then the connecting electrically conducting wires such as copper wires transfer the signal from the pickup coil of the probe to the input coil surrounding SQUID sensor. It is noticed that the signal transferring means the level of magnetic signal intensity could be amplified from the pickup coil to the input coil by adequate designs of those, rather than only the signal propagation.

The present invention relates to a probe-type superconducting quantum interference device (SQUID) system for detecting magnetic particles within a living organism, comprising: (a) a probe union, which has a double D-shape pickup coil inserted in the center of a excitation coil, for closing to the living organism, wherein the probe union is coupled with a cooling module such as TE cooler module to avoid power heating, (b) a SQUID union comprising a SQUID surrounded by a input coil is inserted in a Dewar and within a shielding can, and (c) a connecting electrically conducting wire such as copper wire for transferring the signal from the pickup coil of the probe to the input coil.

The term “SQUID” used herein refers to superconducting quantum interference device (SQUID), is a sensitive detector which is used to measure extremely weak signals, such as subtle changes in the human body's electromagnetic energy field based on the quantum mechanical Josephon effect. A Josephson junction is made up of two superconductors, separated by an insulating layer so thin that electrons can tunnel through. A SQUID consists of tiny loops of superconductors employing Josephson junctions to achieve superposition: each electron moves simultaneously in both directions. Because the current is moving in two opposite directions, the electrons have the ability to perform as qubits (that theoretically could be used to enable quantum computing).

The term “TE cooler module” used herein refers to use the Peltier effect to create a heat flux between the junction of two different types of materials. A Peltier cooler, heater, or thermoelectric heat pump is a solid-state active heat pump which transfers heat from one side of the device to the other side against the temperature gradient (from cold to hot), with consumption of electrical energy. Such an instrument is also called a Peltier device, Peltier diode, cooling diode, Peltier heat pump, solid state refrigerator, or thermoelectric cooler (TEC). Because heating can be achieved more easily and economically by many other methods, Peltier devices are mostly used for cooling. However, when a single device is to be used for both heating and cooling, a Peltier device may be desirable. Simply connecting it to a DC voltage will cause one side to cool, while the other side warms. The effectiveness of the pump at moving the heat away from the cold side is totally dependent upon the amount of current provided and how well the heat from the hot side can be removed.

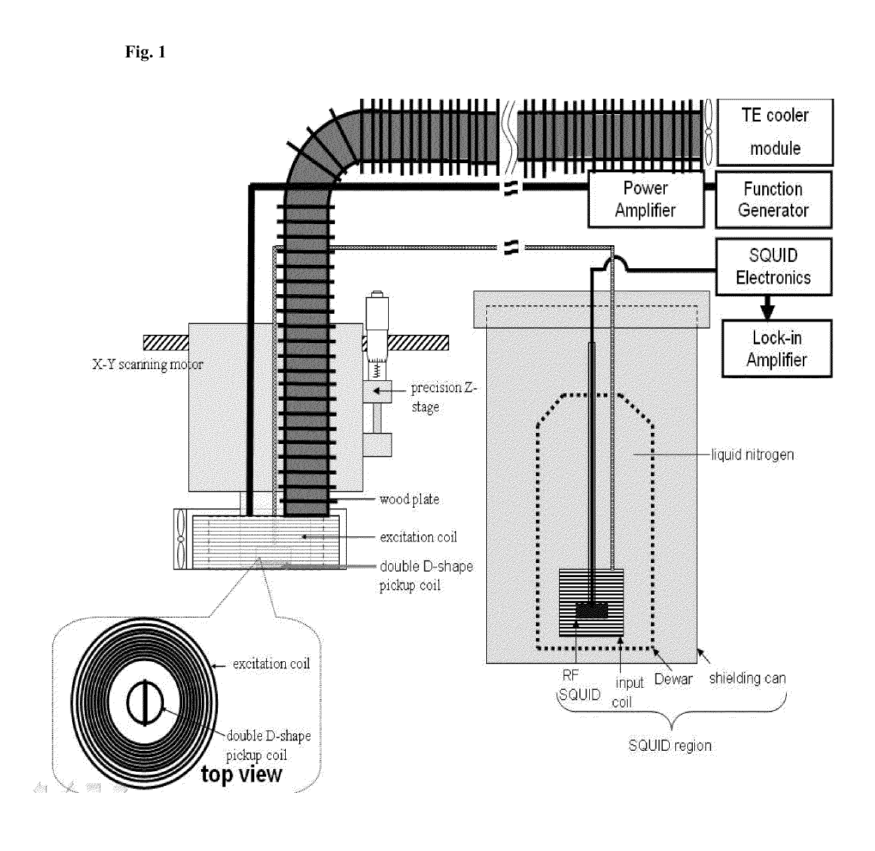

FIG. 1 shows the three major parts, i.e. the probe union, SQUID union, and the connecting electrically conducting wires, for constructing this probe-type SQUID system. In the probe union, the double D-shape pickup coils of 10 mm in diameter, wound oppositely (labeled “\textcircled{x}” and “\textcircled{•}”) of 300 turns in two D-shapes, was inserted in the center of the cylindrical excitation coil of 4 cm and 8 cm in inner and outer diameter as well as wound in 880 numbers. For pickup coils, the coplanar double D-shape scheme, viewed as the planar first-order gradiometer, is superior to minimize in not only the ambient noise but also the background signal like excitation field (Chieh J. J., et al., “The characterization of a sensitive room-temperature probe for use in a SQUID nondestructive evaluation system,” Supercond. Sci. Technol., 22, 015015, 2009). Besides, the optimum design of the pickup coil matching with the input coil makes the transfer efficiency (Kondo T and Itozaki H, “Normal conducting transfer coil for SQUID NDE,”Supercond. Sci. Technol. 17 459, 2004) around 28, which indicated that the field at the input coil is enlarged than that at the pickup coils, and undoubtedly better than the sensed-field decay occurred from the unavoidable distance between the specimen and the SQUID sensor like the deware thickness or vacuum gap. The connection between the input coil and the pickup coil used for example is a copper wire (commercial polyurethane-enameled-copper-wire) which is twisted and shielded by layers of aluminum foil, copper mesh and carbon cloth to suppress the noise. So the probe can be connected to the SQUID union with flexibility, and is installed on an X-Y stepper motor for scanning with a speed of 2 mm s⁻¹. Further, between the pickup coils and input coil, a G-10 cube with high thermal resistance is utilized to avoid the power heating of excitation coil. Besides the G-10 cube, a cooling mechanism is to actively eliminate the thermal load and descript as follows. The probe is enveloped in the acrylic cavity with two side holes, cold air inlet and hot air outlet. Two air pipes are used to connect the cold air inlet to TE cooler module and hot air outlet to a fan, separately. Although the probe could be handy scanning along the contour of any object, the distance between the specimen and the probe is controlled by a precision Z-stage to avoid its influence on the sensed intensity. And the probe scanning is done by programmed X-Y motor to precisely positioning underneath magnetic nanoparticles below the tissue.

In SQUID union, an rf high-T_{c} SQUID surrounded by the input coil was inserted in the deware filled with liquid nitrogen and within the electromagnetically shielding can (MAS-C105, MagQu Co. Ltd.). The shielding can is composed of five sub-cylindrical cans by different materials and structures, and results in the satisfying shielding factor from 80˜100 dB ranged from DC to 1 kHz.

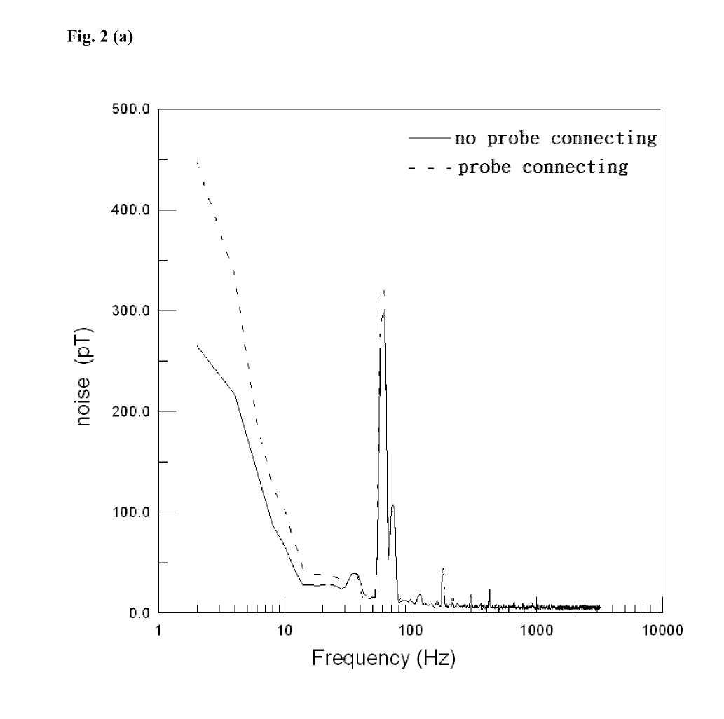

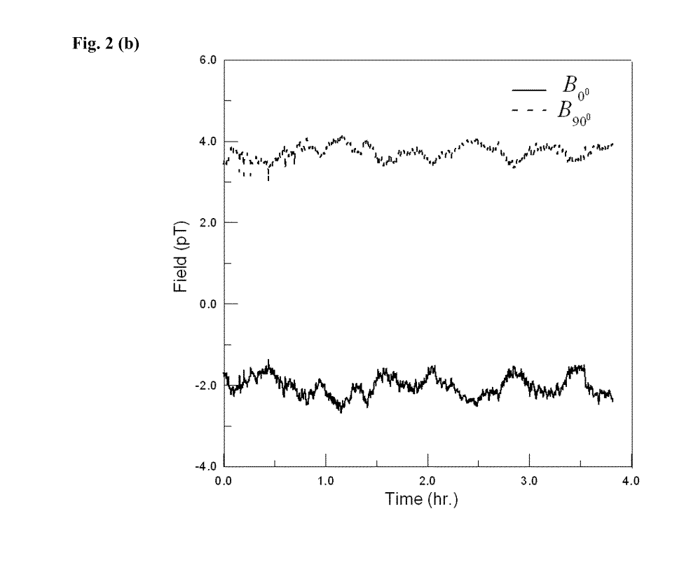

Based on the design of double D-shape pick-up coils, the surrounding noise and excitation field could be suppressed effectively. The connecting wire between the pickup coil of the probe and the input coil of the SQUID union is twisted and shielded by some shielding materials for anti-coupling the surrounding noise. Besides, some electronics like the power supply for excitation filed, etc. are also shielded by adequate metal plates. The most important of all, not only the intrinsic thermal noise of metallic pickup coil is controlled by the optimum design, but also that influenced by the heat from the excitation coil of 60 W is suppressed by the cooling mechanism, as shown in the FIG. 1. The noise spectrum in FIG. 2(a) indicates the noise of this instrument at operating frequency of 400 Hz is around 7 pT, similar with that of only the SQUID sensor in shielding can. It identifies no influence of the intrinsic thermal noise and coupled environment noise on the SQUID sensitivity. Further, the long-term stability testing of the instrument is shown in FIG. 2(b). Due to the cooling mechanism with the optimum cooling capacity of 106 W, the heat generated from the excitation coil could be effective suppressed, and the in-phase intensity B_{0°} and the out-of phase intensity B_{90°} show a good stability.

The present invention further relates to a noninvasive method for detecting magnetic particles within a living organism by a probe-type SQUID comprising (a) a probe union, which has a double D-shape pickup coil inserted in the center of a excitation coil, for apprpaching to a sample, wherein the probe union is coupled with a cooling module such as TE cooler module to avoid power heating, (b) a SQUID union comprising a SQUID surrounded by a input coil is inserted in a Dewar and within a shielding can, and (c) a connecting electrically conducting wire such as copper wire for transferring the signal from the pickup coil of the probe to the input coil, the method comprises (1) approaching the living organism with the probe to magnetize and sense signal from the living organism, (2) the connecting electrically conducting wires such as copper wires transfer the signal from the pickup coils of the probe to the input coil surrounding SQUID sensor, and (3) generating magnetic signal intensity to evaluate the magnetic particles in the living organism.

The method can be applied to detect magnetic particles within a living organism, which are indicators related to Wilson disease, diseases of iron deficiency anemia, or hemochromatosis without biopsy or MRI method. Also, the other applications like detecting magnetic labeling bound to target proteins, moleculars, tumor treatment, drug deliver, tumor diagnosis or immunoassays, can all use the method of the present invention to detect the magnetic particles with high sensitivity. The magnetic labeling can be ferri- or ferromagnetic particles themselves may be of any material which, although preferably non-radioactive (unless the particles are also intended to be detected by their radioactive decay emissions), exhibits ferri- or ferromagnetism in domain and sub-domain sized crystals. Conveniently the particles will be of a magnetic metal or alloy, e.g. of pure iron, but more preferably they will be of a magnetic iron oxide, e.g. magnetite, or a ferrite such as cobalt, nickel or manganese ferrites.

### EXAMPLE

The examples below are non-limiting and are merely representative of various aspects and features of the present invention.

### Example 1

### Ex-Vivo Test: Tracking Particles

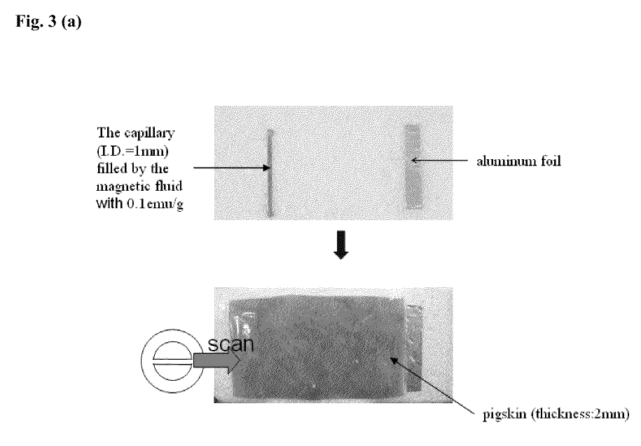

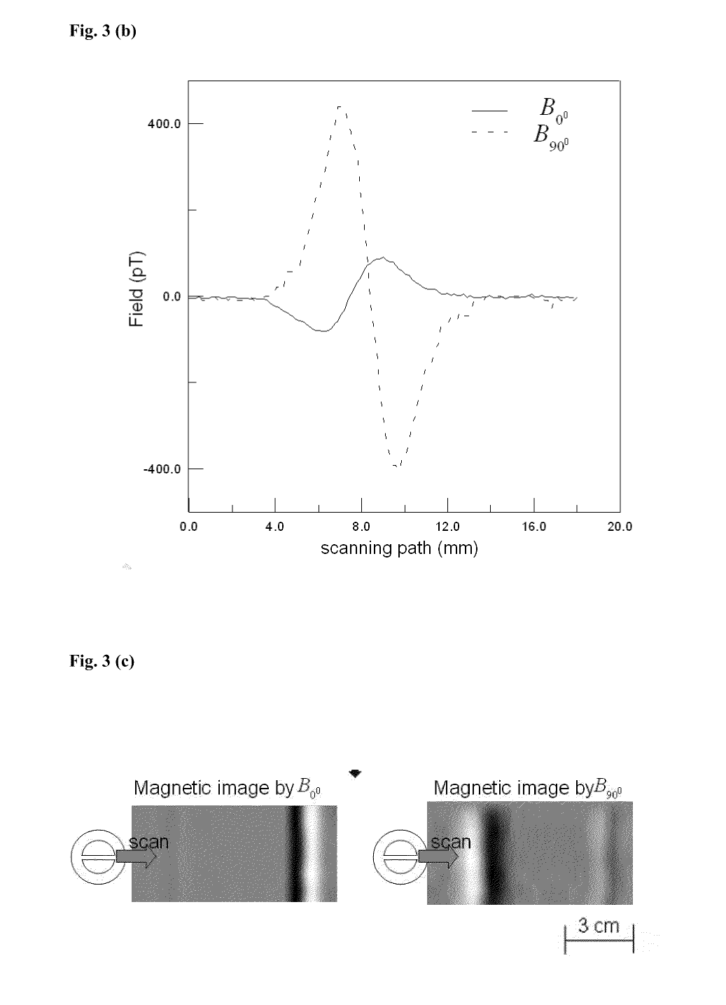

Magnetic nanoparticles for drug deliver or magnetic labeling of tumors always flow inside the vessel. In order to simulate this bio-condition, the capillary of 0.9 mm in inner diameter similar with the vessel size of human beings and 2 cm in length was used to fill the magnetic fluids, and then placed in the polystyrene cavity and covered by the pig skin of 2 mm thickness, as shown in FIG. 3(a). Here, there are no needs of micro-pumps because the flowing of magnetic nanoparticles has no influence on the sensitivity.

In another consideration, the measured magnetic signal always is necessarily mapped onto the torso for the surgery information. For example, the research on integrated MEG/MRI emerges recently (Zotev V S, et al., “Microtesla MRI of the human brain combined with MEG,” J. Magn. Reson. 194 115, 2008). Therefore the aluminum foil as the reference is pasted on the polystyrene plate in 3 cm distance from the capillary. It simulated the future clinic examination way that the probe scans around the contours of the torso with some pasted aluminum foils on the skin to find out the relative position of injected bio-function magnetic nanoparticles bound to the bio-target within the torso.

After controlling the distance between the probe and the pig skin, the probe scanned the pig skin in the speed of 2 mm/s in x direction for one round trip by X-Y stepper motor. And the step in y direction was 1.5 cm due to the spatial resolution around 1.1 cm.

The typical scanning pattern, i.e. the variation of B_{0°} and B_{90°} with the scanning path, is as shown in FIG. 3 (b), in which the filled capillary of 1 mm in inner diameter with magnetic fluids of 0.1 emu/g in concentration. It is noticed that the magnetic-fluid concentration of 0.1 emu/g equal to 1000 mg/kg, less than the tolerable, safe, and biocompatible criteria of 3150 mg/kg in subcutaneous tumor therapy. Here, the conversion is according to the saturation magnetism of 1.60768×10⁻¹⁴ emu and 1.67467×10⁻¹⁶ g per adopted magnetic particle with the average diameter of 40 nm. In FIG. 3(b), the sinusoidal variation occurs from each part of the D-shaped pickup coil near to, across, and far away from the filled capillary.

By constructing the scanning pattern of B_{0°} and B_{90°}, magnetic images are presented as FIG. 3(c). Because the magnetism reply of the aluminum foil is opposite to that of the magnetic nanoparticles, the B_{0°} image shows the clear shape of only the aluminum foil, but the B_{90°} image clearly indicates the shapes of the brighter capillary and the darker aluminum foil. The results show the feasibility of fast tracing of the injected magnetic particles before that metabolized out the torso. Besides, those images could be used to map the position of the injected magnetic particles onto the torso by relating to the reference landmark, like function of the X-ray photo or MRI photo.

### Example 2

### Monitoring Dynamics of Particles

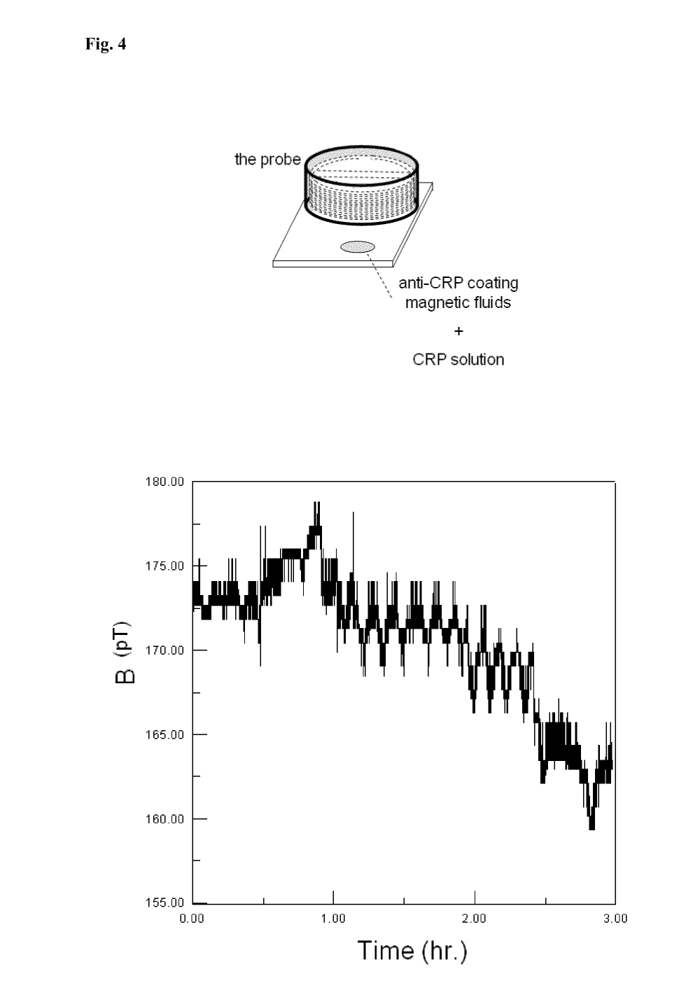

In magnetic labeling application, the bio-function magnetic nanoparticles, flowing in the blood vessel or injected in the well plate, are bound to the tumor or bio-targets if those touch the targets. After binding to the bio-targets, the magnetic nanoparticles could not rotate free and results in the reduction of AC susceptibility. The larger the tumor size or the more bio-target proteins, the more the bound nanoparticles. Magneto reduction assay is based on the way to determine the biotarget amount by the reduction percentage (J. J. Chieh et al., “Hyper-high-sensitivity wash-free magnetoreduction assay on biomolecules using high-T_{c} superconducting quantum interference devices”, J. Appl. Phys., 03, 014703-1˜6, 2008). Beyond tracking these particles, in order to valid the feasibility of monitoring the dynamic of those particles like a bio junction process by this instrument, the ex-vivo immunoassay was performed, too. A hole of 1 cm in diameter drilled in the acrylic plate of 2 cm thick was filled with anti-CRP coating magnetic fluids with the concentration of 0.1 emu/g and 0.8 c.c. and CRP solution of 0.1 mg/L and 0.1 c.c. initially and sealed by transparent thin-film. At first, the distance between the probe and the hole is controlled at 2 mm apart. By scanning across the filled hole, the best position for the largest amplitude of B_{0°} and B_{90°} was found to position the probe for the static measurement in long-term period. FIG. 4 shows that the intensity B, derived from \sqrt{B_{0°}²+B_{90°}²}, varies with the time. The intensity B initially kept constant, and then decreased and finally reached stable. The variation ratio (Bᵢ−B_{f})/Bᵢ was around 5.7%, in which Bᵢ and B_{f} is the average value in initial and final stable stage. The phenomenon agreed with the former ImmunoMagnetic Reduction (J. J. Chieh et al., “Hyper-high-sensitivity wash-free magnetoreduction assay on biomolecules using high-T_{c} superconducting quantum interference devices”, J. Appl. Phys., 03, 014703-1˜6, 2008), and demonstrates that this proposed instrument works for not only the amount of magnetic nanoparticles but also the tiny and dynamic variation from some parts of magnetic nanoparticles based on the high stability for the long time.

### Example 3

### Sensitivity

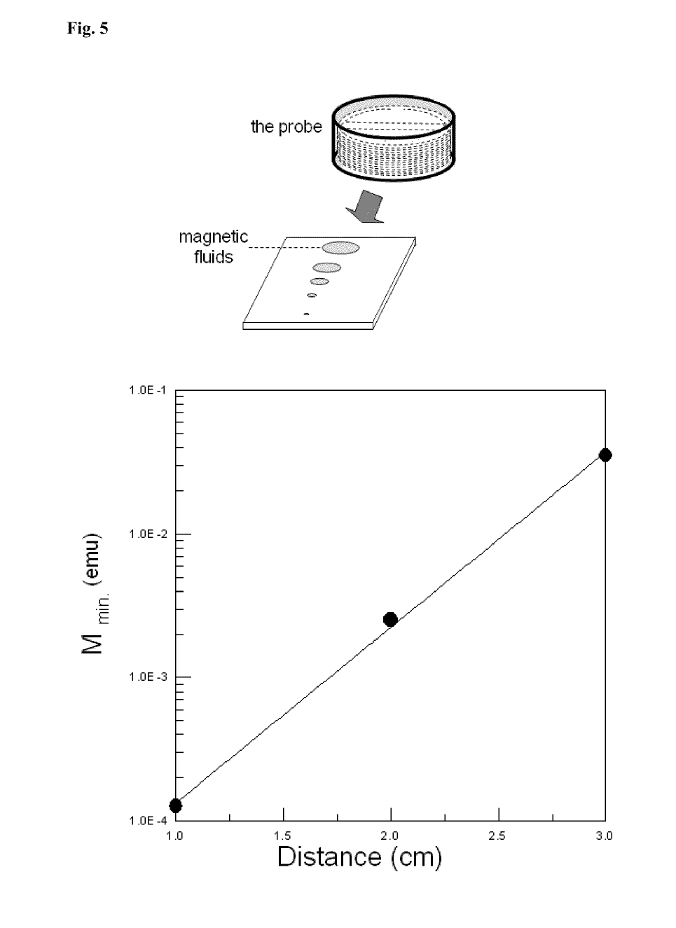

Following the measurement of the tiny field variation of bio junction process, the sensitivity of the instrument is necessarily quantified. The cylindrical holes with the diameters from 0.5 mm to 1 mm and the depth of 2 mm are filled with magnetic fluids with different concentrations. The minimum amount of the detectable magnetic nanoparticles, determined from the product of the magnetic-fluid concentration and the hole volume, at different distances is used as an indicator. Here, the detectable signal is defined as SNR larger than 2. FIG. 5 shows that the sensitivity reaches around 6.28×10⁻⁴ emu of saturation magnetism up to 3 cm.

If all theses magnetic particles could be bound to prostate tumor or breast tumor, the minimum detected sizes of the prostate tumor or breast tumor is 0.38 mm and 0.17 mm in diameter in depth of 1 cm, separately, by the information of 33000 and 330000 magnetic particles for each prostate and breast tumor cell. In other words, the high sensitivity for the breast tumor of 1.16 mm in size and 3 cm in depth is feasible and better than the current clinic examination (Mital M. and Pidaparti M. R., “Breast Tumor Simulation and Parameters Estimation Using Evolutionary Algorithms,” Journal of Modelling and Simulation in Engineering 2008, 756436, 2008). Besides, based on the sensitivity of this depth and the volume, the skin tumor is also undoubtedly examined well because the skin tumor in early stage is as large as 0.76 mm in diameter and located in the depth deeper than 1.4 mm (Marks R, “An overview of skin cancers,” Cancer, 75, 607, 1995 and Lavker M. R., et al., “Hair follicle stem cells: Their location, role, in hair cycle, and involvement in skin tumor formation,” J. Invest. Dermatol. 101 16S, 1993).

### Example 4

### In-Vivo Test

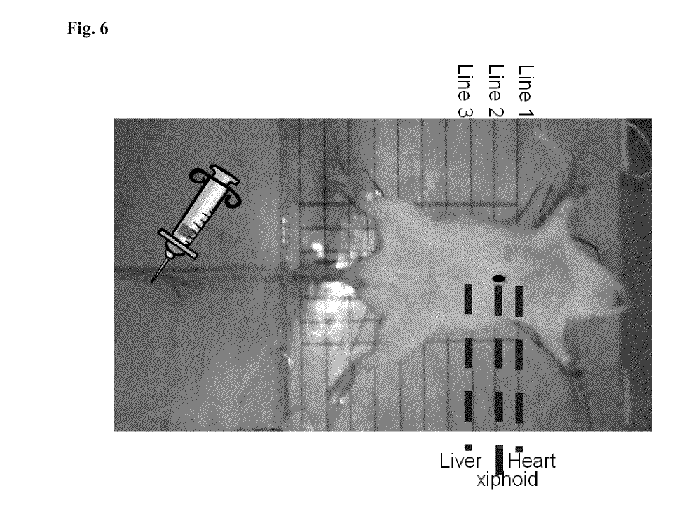

In order to demonstrate no influence of the susceptibility of bloods, tissues, etc. on the measurement of magnetic nanoparticles within the torso, the in-vivo test of injecting magnetic fluids was executed by the probe over the studying organs of individual rat. So the position of studying organs was necessarily pointed out onto the rat torso at first by some steps. The xiphoid, representative of the boundary between the thoracic cavity and abdominal cavity, was marked onto the anesthetized rat, as shown in FIG. 6. And the xiphoid of the anesthetized rat bound to the board was aligned through line 2 of the coordinates labeled on the board. Due to the considerations for physiology locations of heart and liver organs along with the spatial resolution of the instrument around 1.1 cm, the coordinate lines, Line 1 and Line 3, across the heart and liver separately were 2 cm away from Line 2. Because the injected magnetic nanoparticles flow through a liver and heart with the blood circulation inside the torso, the probe scanned along the appropriate line for in-vivo measuring the magnetic nanoparticles in specific organs. Here, the magnetic fluids of 0.9 emu/g and 0.3 c. c. were injected into the tail vena of wistar rat (male, five weeks old).

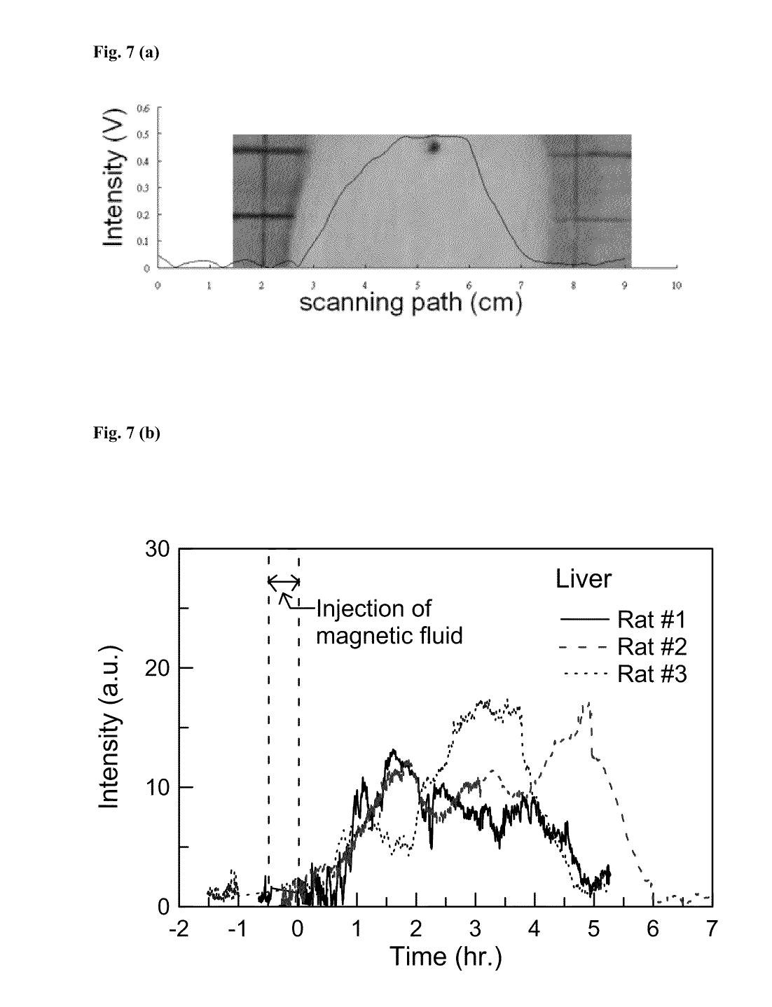

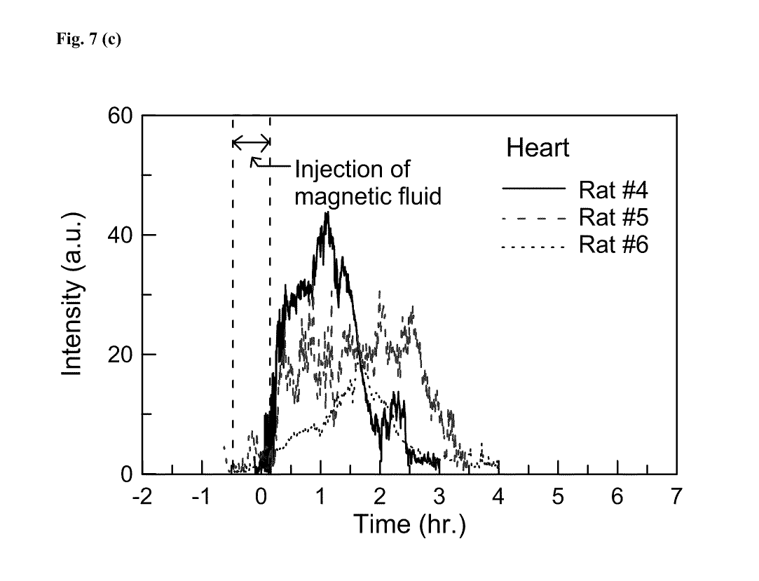

By scanning across the specific organ along the relative coordinate line in advance, the scanning pattern of the specific organ could be found as shown in FIG. 7(a), and then the best position for its peak was, too. Consequently the probe stayed at this position for long-term measurement. For example, FIG. 7(b) is the variation of the normalization intensity B at the liver with the time. Time 0 is chosen at finishing injection of magnetic fluids. It shows that although the normalization B was stable before Time 0 while the rat was anesthetized, many noise peaks occurred near Time 0 due to the rat struggling under the injecting magnetic fluids. Here, the normalization B was defined as \sqrt{(B_{0°}−B_{0°,i,avg})²+(B_{90°}−B_{90°,i,avg})²}/\sqrt{(B_{0°,i}−B_{0°,i,avg})²+(B_{90°,i}−B_{90°,i,avg})²}|_{avg}, where the suffix i was representative of the initial period before Time 0 except the time during rat struggling, and avg was the average value of all data in this stage. After Time 0, the normalization B initially kept at the level of that before Time 0 except the injecting period, increased greatly to the maximum level around 1 hr., retained stable for 4 hrs, then decreased to the original level. The model was identified by three rats, and the accumulation time for the largest amount of magnetic nanoparticles in rat liver coincides with the results of a tissue examine (F. J. Lazaro et al., “Magnetic characterisation of rat muscle tissues after subcutaneous iron dextran injection,” Biochimicaet Biophysica Acta, 740, 434-445, 2005). Further, in order to study the responses of some important organs like the heart besides the liver in the same injected rat, one more rat was performed by scanning the liver and the heart separately in turns, instead of the long-term measurement. The liver response of the scanned rat in FIG. 7(c) was agreed with the trend in FIG. 7(b). However, the heart response in FIG. 7(c) is that the intensity B increased soon but few after injecting magnetic fluids, and finally returned to its original level. These results could be explained by a well-known physiological model and described simply as follows (L. Gutierrez, et al., “Bioinorganic transformations of liver iron deposits observed by tissue magnetic characterisation in a rat model,” Journal of Inorganic Biochemistry, 100, 1790-1799, 2006). The injected magnetic nanoparticles flows from the rat tail by veins, through the heart, and then are pumped to different organs within the torso like the liver. However, those particles are just circulated through the heart, and then the concentration of magnetic particles in the blood vessel does not vary largely and quickly due to the metabolism of the living organism. Oppositely, injected particles are accumulated in the liver because macrophages most distributed in the liver swallow up those viewed as bacteria once those flows through the liver. Finally, those swallowed particles are exhausted out from macrophages into the blood for excreta organs because magnetic nanoparticles rather than iron dextran could not be ionized for binding with ferritins. Therefore it indicates this instrument has the feasibility of the fast scanning for diagnosis different organism within the torso. The high convenience and sensitivity makes the current SQUID biomagnetism system hard to compatible.

What is claimed is:

1. A probe-type superconducting quantum interference device (SQUID) for detecting magnetic particles within a living organism, comprising
(a) a probe union, which has a double D-shape pickup coil inserted in the center of a excitation coil, for approaching to the living organism, wherein the probe union is coupled with a cooling module to avoid power heating,
(b) a SQUID union comprising a SQUID surrounded by a input coil is inserted in a Dewar and within a shielding can, and
(c) a connecting electrically conducting wire for transferring the signal from the pickup coil of the probe to the input coil.

2. The probe-type SQUID of claim 1, wherein the double D-shape pickup coil wind oppositely to minimize in not only ambient noise but also background signal.

3. The probe-type SQUID of claim 1, wherein the cooling module is TE cooler module.

4. The probe-type SQUID of claim 1, which further comprises a G-10 cube with high thermal resistance to avoid power heating of the excitation coil.

5. The probe-type SQUID of claim 1, wherein the probe union is enveloped in an acrylic cavity with two holes for cold air inlet and hot air inlet, and two air pipes are used to connect the cold air inlet to the TE cooler module and hot air outlet to a fan, separately.

6. The probe-type SQUID of claim 1, wherein distance between the sample and the probe union is controlled by a precision Z-stage.

7. The probe-type SQUID of claim 1, wherein the probe union scans magnetic particles inside the living organism, which is done by a programmed X-Y motor.

8. The probe-type SQUID of claim 1, wherein the Dewar is filled with liquid nitrogen.

9. The probe-type SQUID of claim 1, wherein the connecting electrically conducting wire is cooper wire.

10. The probe-type SQUID of claim 1, wherein the connecting copper wire is twisted and shielded by shielding materials for anti-coupling surrounding noise.

11. The probe-type SQUID of claim 1, wherein the magnetic particles are indicators related to Wilson disease, diseases of iron deficiency anemia, or hemochromatosis.

12. The probe-type SQUID of claim 1, which can be used to detect magnetic-labeling indicators for immunoassays or tumor diagnosis in a living organism.

13. A noninvasive method for detecting magnetic particles within a living organism by a probe-type SQUID comprising (a) a probe union, which has a double D-shape pickup coil inserted in the center of a excitation coil, for approaching to a living organism, wherein the probe union is coupled with a cooling module to avoid power heating, (b) a SQUID union comprising a SQUID surrounded by a input coil is inserted in a Dewar and within a shielding can, and (c) a connecting electrically conducting wire for transferring the signal from the pickup coil of the probe to the input coil, the method comprises (1) approaching the living organism with the probe to magnetize and sense signal from the living organism, (2) the connecting copper wires transfer the signal from the pickup coils of the probe to the input coil surrounding SQUID sensor, and (3) generating magnetic signal intensity to evaluate the magnetic particles in the living organism.

14. The method of claim 11, wherein the magnetic particles are indicators related to Wilson disease, diseases of iron deficiency anemia, or hemochromatosis.
